(19) United States
(12) Patent Application Publication
(10) Pub. No.: US 2015/0280043 A1
(43) Pub. Date: Oct. 1, 2015

(54) SOLAR CELL WITH TRENCH-FREE EMITTER REGIONS

(71) Applicant: David D. Smith, Campbell, CA (US)

(72) Inventor: David D. Smith, Campbell, CA (US)

(21) Appl. No.: 14/227,965

(22) Filed: Mar. 27, 2014

(51) Int. Cl. H01L 31/068; H01L 31/18; H01L 31/0224

(52) U.S. Cl. CPC H01L 31/068; H01L 31/022425; H01L 31/182; H01L 31/1864; H01L 31/1872

(57) ABSTRACT

Methods of fabricating solar cells having trench-free emitter regions, and the resulting solar cells, are described. In an example, a solar cell includes a substrate having a light-receiving surface and a back surface. A thin dielectric layer is disposed on a portion of the back surface of the substrate. A first polycrystalline silicon emitter region is disposed on a first portion of the thin dielectric layer and doped with an impurity of a first conductivity type. A second polycrystalline silicon emitter region is disposed on a second portion of the thin dielectric layer proximate to the first polycrystalline silicon emitter region disposed on the first portion of the thin dielectric layer. The second polycrystalline silicon emitter region is doped with an impurity of a second, opposite, conductivity type. A total concentration of the impurity of the first conductivity type in the first polycrystalline silicon emitter region is at least an order of magnitude greater than a total concentration of the impurity of the second conductivity type in the second polycrystalline silicon emitter region.

### TECHNICAL FIELD

Embodiments of the present disclosure are in the field of renewable energy and, in particular, methods of fabricating solar cells having trench-free emitter regions, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIGS. 1A-1E illustrate cross-sectional views of various stages in the fabrication of a solar cell, in accordance with an embodiment of the present disclosure, wherein:

FIG. 1A illustrates a thin dielectric layer formed on a portion of a back surface of a substrate of a solar cell;

FIG. 1B illustrates the structure of FIG. 1A having a boron-containing silicon layer formed thereon;

FIG. 1C illustrates the structure of FIG. 1B having first regions, but not second regions, of the boron-containing silicon layer implanted with phosphorous ions;

FIG. 1D illustrates the structure of FIG. 1C heated to provide N-type polycrystalline silicon emitters and P-type polycrystalline silicon emitters; and

FIG. 1E illustrates the structure of FIG. 1D following formation of a plurality of conductive contact structures for the N-type polycrystalline silicon emitters and the P-type polycrystalline silicon emitters.

FIG. 2 is a flowchart listing operations in a method of fabricating a solar cell as corresponding to FIGS. 1A-1E, in accordance with an embodiment of the present disclosure.

FIG. 3A schematically illustrates a cross-sectional view of an inline platform for patterned implant involving a traveling wafer and stationary shadow mask, in accordance with an embodiment of the present disclosure.

FIG. 3B illustrates an implant sequence through a graphite proximity mask in the apparatus of FIG. 3A, in accordance with an embodiment of the present disclosure.

FIG. 4 is a flowchart listing operations in another method of fabricating a solar cell, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Methods of fabricating solar cells having trench-free emitter regions, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are methods of fabricating solar cells. In one embodiment, a method of fabricating a solar cell involves forming a thin dielectric layer on a portion of a back surface of a substrate, the substrate having a light-receiving surface opposite the back surface. The method also involves forming a first polycrystalline silicon emitter region on a first portion of the thin dielectric layer and doped with an impurity of a first conductivity type. The method also involves forming a second polycrystalline silicon emitter region on a second portion of the thin dielectric layer proximate to the first polycrystalline silicon emitter region, the second polycrystalline silicon emitter region doped with an impurity of a second, opposite, conductivity type. A total concentration of the impurity of the first conductivity type in the first polycrystalline silicon emitter region is at least an order of magnitude greater than a total concentration of the impurity of the second conductivity type in the second polycrystalline silicon emitter region.

In another embodiment, a method of fabricating alternating N-type and P-type emitter regions of a solar cell involves forming a boron-containing silicon layer above a portion of a substrate by an in situ deposition process. The method also involves implanting first regions, but not second regions, of the boron-containing silicon layer with phosphorous ions to provide phosphorous-implanted regions of the boron-containing silicon layer. The method also involves heating to provide N-type polycrystalline silicon emitters in the first regions and to provide P-type polycrystalline silicon emitters in the second regions. The method also involves forming a plurality of conductive contact structures, each of the N-type polycrystalline silicon emitters and the P-type polycrystalline silicon emitters electrically connected to one of the plurality of conductive contact structures.

Also disclosed herein are solar cells. In one embodiment, a solar cell includes a substrate having a light-receiving surface and a back surface. A thin dielectric layer is disposed on a portion of the back surface of the substrate. A first polycrystalline silicon emitter region is disposed on a first portion of the thin dielectric layer and doped with an impurity of a first conductivity type. A second polycrystalline silicon emitter region is disposed on a second portion of the thin dielectric layer proximate to the first polycrystalline silicon emitter region disposed on the first portion of the thin dielectric layer. The second polycrystalline silicon emitter region is doped with an impurity of a second, opposite, conductivity type. A total concentration of the impurity of the first conductivity type in the first polycrystalline silicon emitter region is at least an order of magnitude greater than a total concentration of the impurity of the second conductivity type in the second polycrystalline silicon emitter region.

One or more embodiments described herein are directed to solar cells having emitter regions form above a substrate of the solar cell and, particularly, to such solar cells having a trench-free arrangement of the emitter regions. For reference, state-of-the-art solar cells having emitter regions formed in a polycrystalline silicon layer on a back surface of a back contact solar cell often have gaps separating N-type and P-type emitter regions. Furthermore, the gap is often extended to form a trench that extends into the underlying substrate. As such, such solar cells can be referred to as trench-contact solar cells. By contrast, one or more embodiments described herein are directed to solar cell process flows that that provide trench-free arrangements in a simplified manner by using ion implantation.

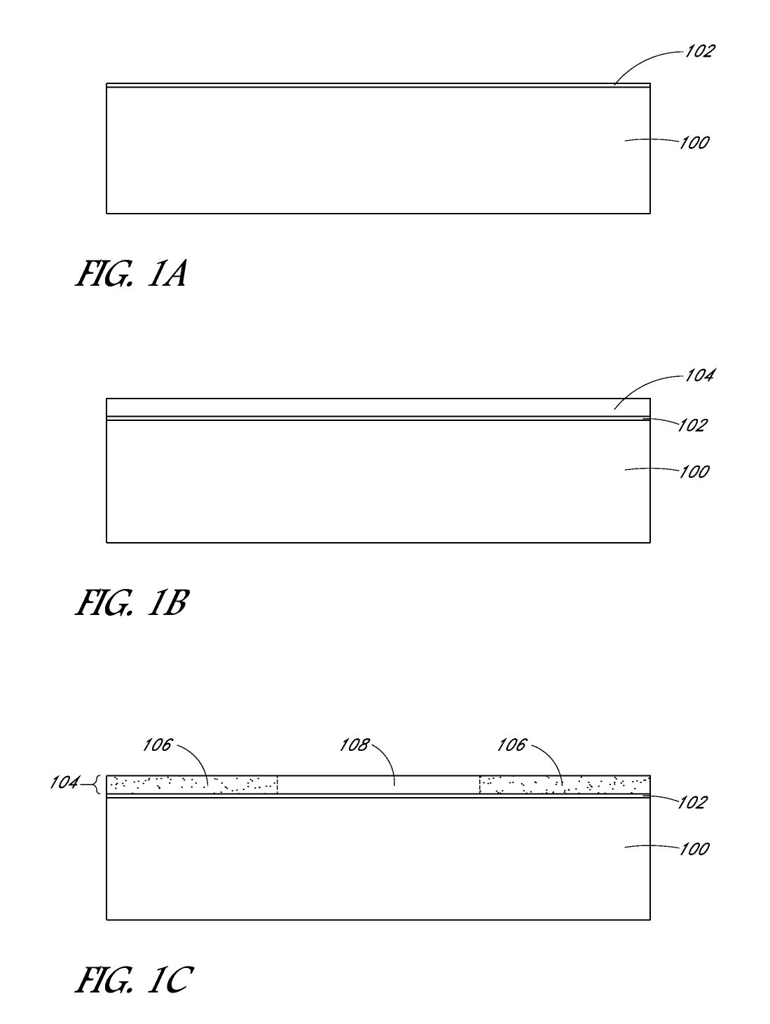

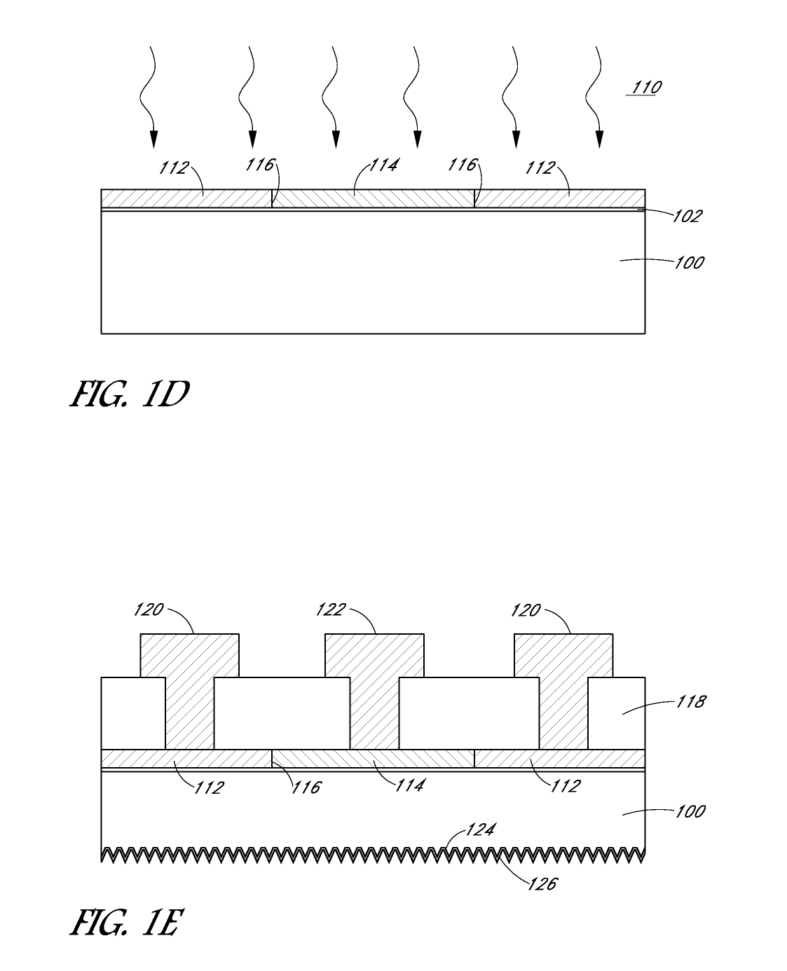

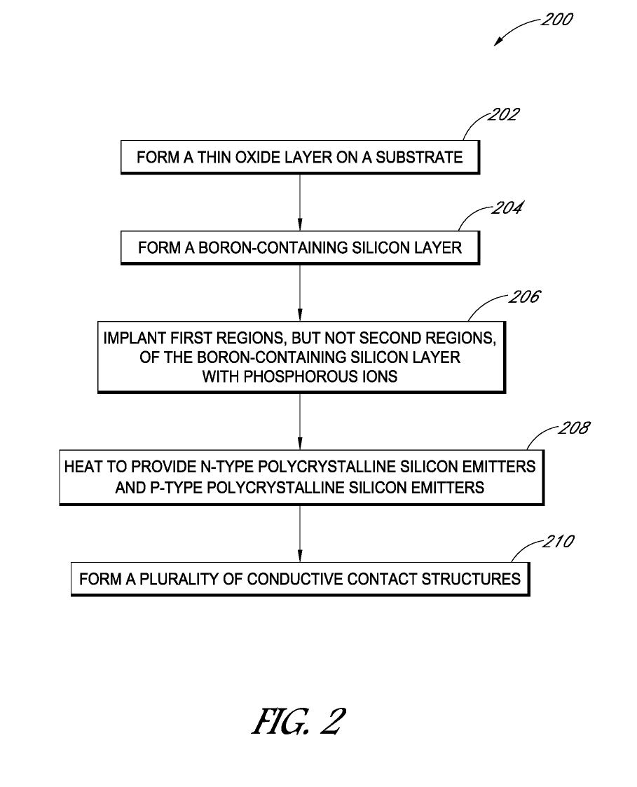

In accordance with general embodiments of the present disclosure, processes are described based on the discovery that light boron doping in a P-type polycrystalline silicon “finger” may be essential for eliminating space charge recombination in a trench-free back contact solar cell. In an embodiment, since a lowering of the respective N-type polycrystalline silicon doping concentration may not be necessary, a low level boron-doped region is formed in both P-type and N-type fingers, setting the P-type fingers at a concentration of approximately 1e19 cm⁻³ boron. Meanwhile, the low level boron doping is counter-doped in the N-type regions with phosphorous at a concentration of approximately 1e20 cm⁻³ to provide the N-type fingers. As described in association with FIGS. 1A-1E below, one implementation may involve initial formation of a plasma-generated P+ doped silicon layer followed by a shadow masked implant of phosphorous to convert regions of the P+ doped silicon layer to N-type fingers or dots. A thermal operation may be performed similar to activate the dopants, crystallize the emitter regions and, possibly, passivate the front surface of the solar cell.

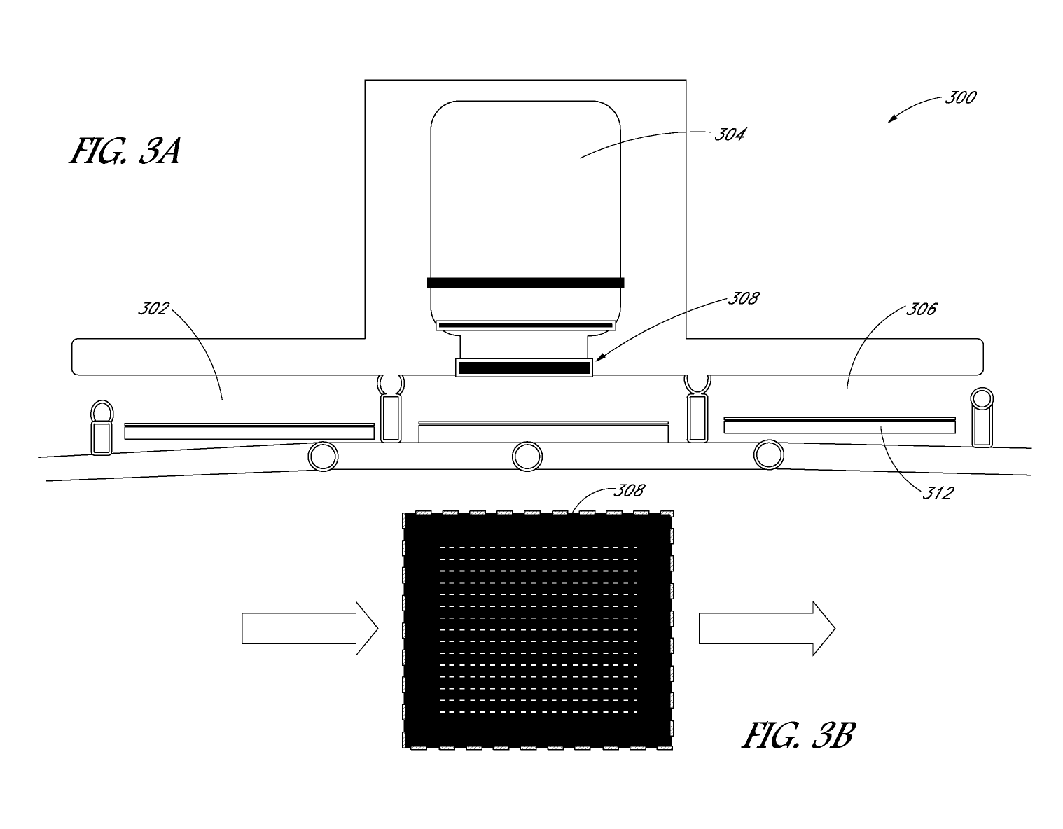

In accordance with an exemplary embodiment, a method of fabricating a solar cell involving fabricating alternating N-type and P-type emitter regions of the solar cell is disclosed. FIGS. 1A-1E illustrate cross-sectional views of various stages in the fabrication of a solar cell, in accordance with an embodiment of the present disclosure. FIG. 2 is a flowchart 200 listing operations in a method of fabricating a solar cell as corresponding to FIGS. 1A-1E, in accordance with an embodiment of the present disclosure.

Referring to FIG. 1A, and to corresponding operation 202 of flowchart 200, a thin dielectric layer 102 is formed on a portion of a back surface of a substrate 100 of a solar cell.

In an embodiment, the substrate 100 is a monocrystalline silicon substrate, such as a bulk single crystalline N-type doped silicon substrate. It is to be appreciated, however, that substrate 100 may be a layer, such as a multi-crystalline silicon layer, disposed on a global solar cell substrate. In an embodiment, the thin dielectric layer 102 is a tunneling silicon oxide layer having a thickness of approximately 2 nanometers or less.

Referring to FIG. 1B, and to corresponding operation 204 of flowchart 200, a boron-containing silicon layer 104 is formed on the thin dielectric layer 102.

In an embodiment, the boron-containing silicon layer 104 forming a boron-containing silicon layer above a portion of a substrate by an in situ deposition process where the boron impurity is incorporated into the silicon layer at the time of formation of the silicon layer. In one such embodiment, forming the boron-containing silicon layer 104 involves forming a boron-containing amorphous silicon layer. In another such embodiment, forming the boron-containing silicon layer 104 involves forming a boron-doped polycrystalline silicon layer. In the former embodiment, the boron-containing amorphous silicon layer is a boron-containing hydrogenated silicon layer formed using plasma enhanced chemical vapor deposition (PECVD), represented by boron-doped a-Si:H, which includes S—H covalent bonds throughout the layer. Other forms of CVD may also be applicable such as atmospheric CVD or low pressure CVD. In the latter embodiment, the boron-doped polycrystalline silicon layer is formed using a PECVD process. It is to be appreciated that in other embodiments, the boron impurity may be incorporated into a silicon layer following formation of the silicon layer, e.g., by a global implant process.

Referring to FIG. 1C, and to corresponding operation 206 of flowchart 200, first regions 106, but not second regions 108, of the boron-containing silicon layer 104 are implanted with phosphorous ions.

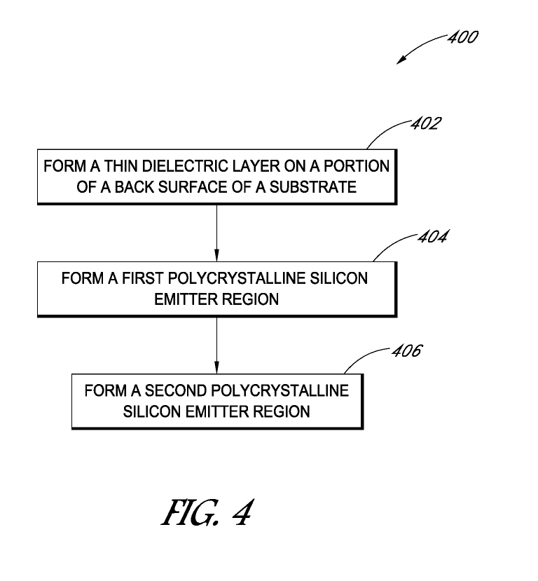

In an embodiment, the first regions 106 are implanted to provide phosphorous-implanted regions 106 of the boron-containing silicon layer 104 where the concentration of the phosphorous impurity of the phosphorous-implanted regions 106 is at least 10-fold (i.e., at least one order of magnitude) greater than the concentration of boron impurity in the regions 106 and, hence, at least one order of magnitude greater than the concentration of boron impurity in the non-phosphorous-implanted regions 108. In one embodiment, implanting the boron-containing silicon layer 104 with phosphorous ions involves implanting through a shadow mask, an exemplary process tooling for which is described below in association with FIGS. 3A and 3B. In a specific such embodiment, the implanting is performed through a graphite shadow mask positioned off of, but in close proximity to, the boron-containing silicon layer 104. In another specific embodiment, the implanting is performed through a silicon shadow mask positioned on the boron-containing silicon layer 104. In an embodiment, the implanting is performed by using ion beam implantation or plasma immersion implantation. It is to be appreciated that some residual doping of the second regions may actually occur, e.g., through scatter or imperfect doping. However, any such residual doping is not sufficient to counter-dope the second regions 108.

Referring to FIG. 1D, and to corresponding operation 208 of flowchart 200, the structure of FIG. 1C is heated 110 to provide N-type polycrystalline silicon emitters 112 and P-type polycrystalline silicon emitters 114.

In an embodiment, the heating is an annealing process, such as a rapid thermal annealing process, used to activate the impurities in the first and second regions 106 and 108, respectively, of the boron-containing silicon layer 104. In one embodiment, the annealing is performed at a temperature approximately in the range of 850-1100 degrees Celsius for a duration approximately in the range of 1-100 minutes. In one embodiment, the boron-containing silicon layer 104 is a boron-containing amorphous silicon layer, and the heating 110 involves crystallizing the boron-containing amorphous silicon layer to form boron-doped polycrystalline silicon in addition to activating the impurities. In another embodiment, the boron-containing silicon layer 104 is a boron-doped polycrystalline silicon layer, and the heating 110 involves at least activating the phosphorous impurity of the phosphorous-implanted regions to form phosphorous-doped regions. In an embodiment, a light phosphorous dopant drive is performed during the heating or annealing.

Thus, first polycrystalline silicon emitter regions 112 are formed on a first portion of the thin dielectric layer 102 and are doped with an N-type impurity. Second polycrystalline silicon emitter regions 114 are formed on a second portion of the thin dielectric layer 102, proximate to the first polycrystalline silicon emitter regions 112. The second polycrystalline silicon emitter regions 114 are doped with a P-type impurity. In one such embodiment, a total concentration of the activated N-type impurity in the first polycrystalline silicon emitter regions 112 is at least an order of magnitude greater than a total concentration of the activated P-type impurity in the second polycrystalline silicon emitter regions 114 and, hence, at least an order of magnitude greater than a total concentration of the activated P-type impurity in the first polycrystalline silicon emitter regions 112. Referring again to FIG. 1D, the heating 110 involves forming a P/N junction 116 between adjacent ones of the N-type polycrystalline silicon emitters 112 and P-type polycrystalline silicon emitters 114.

Referring to FIG. 1E, and to corresponding operation 210 of flowchart 200, the structure of a plurality of conductive contact structures 120/122 is formed for the N-type polycrystalline silicon emitters (corresponding to contact structure 120) and the P-type polycrystalline silicon emitters (corresponding to contact structures 122).

In an embodiment, the conductive contact structures 120/122 are fabricated by first depositing and patterning an insulating layer 118 to have openings and then forming one or more conductive layers in the openings. In one such embodiment, the openings are formed by laser ablation. In an embodiment, the conductive contact structures 120/122 include metal and are formed by a deposition, lithographic, and etch approach or, alternatively, a printing or plating process or, alternatively, a foil adhesion process.

Referring again to FIG. 1E, a light-receiving surface 124, i.e., the surface opposite the surface on which the conductive contact structures are formed, is a texturized light-receiving surface. In one embodiment, a hydroxide-based wet etchant is employed to texturize the front surface of the substrate 102. It is to be appreciated that the timing of the texturizing of the light receiving surface may vary. For example, the texturizing may be performed before or after the formation of the thin dielectric layer 102 but, in one embodiment, prior to the formation of the boron-containing silicon layer 104. In an embodiment, a texturized surface may be one which has a regular or an irregular shaped surface for scattering incoming light, decreasing the amount of light reflected off of the light-receiving surfaces of the solar cell. Referring again to FIG. 1E, additional embodiments can include formation of a passivation and/or anti-reflective coating (ARC) layers (shown collectively as layer 126) on the light-receiving surface 124, such as silicon nitride, silicon, silicon oxide or silicon oxynitride layers. It is to be appreciated that the timing of the formation of passivation and/or ARC layers may also vary.

Referring again to FIG. 1E, then, in an embodiment, a solar cell includes a substrate 100 having a light-receiving surface 124 and a back surface opposite the light-receiving surface. A thin dielectric layer 102 is disposed on a portion of the back surface of the substrate 100. A first polycrystalline silicon emitter region 112 is disposed on a first portion of the thin dielectric layer 102 and doped with an impurity of a first conductivity type. A second polycrystalline silicon emitter region 114 is disposed on a second portion of the thin dielectric layer 102 proximate to the first polycrystalline silicon emitter region 112 disposed on the first portion of the thin dielectric layer 102. The second polycrystalline silicon emitter region 114 is doped with an impurity of a second, opposite, conductivity type. A total concentration of the impurity of the first conductivity type in the first polycrystalline silicon emitter region 112 is at least an order of magnitude greater than a total concentration of the impurity of the second conductivity type in the second polycrystalline silicon emitter region 114. A first conductive contact structure 120 is electrically connected to the first polycrystalline silicon emitter region 112. A second conductive contact structure 122 is electrically connected to the second polycrystalline silicon emitter region 114. In one embodiment the solar cell is a back contact solar cell.

In one embodiment, the solar cell further includes a P/N junction 116 between the first polycrystalline silicon emitter region 112 and the second polycrystalline silicon emitter region 114. In one embodiment, the impurity of the first conductivity type in the first polycrystalline silicon emitter region 112 is an N-type impurity, and the impurity of the second conductivity type in the second polycrystalline silicon emitter region 114 is a P-type impurity. In a specific such embodiment, the N-type impurity is phosphorous and the total concentration of the impurity of the first conductivity type in the first polycrystalline silicon emitter region 112 is approximately 1E20 atoms/cm³. In that embodiment, the P-type impurity is boron and the total concentration of the impurity of the second conductivity type in the second polycrystalline silicon emitter region 114 is approximately 1E18 atoms/cm³.

Based on the nature of the fabrication scheme, in one embodiment, the first polycrystalline silicon emitter region 112 further includes the impurity of the second conductivity type. In a specific such embodiment, the total concentration of the impurity of the first conductivity type in the first polycrystalline silicon emitter region 112 is approximately two orders of magnitude greater than the total concentration of the impurity of the second conductivity type in the second polycrystalline silicon emitter region 114 and in the first polycrystalline silicon emitter region 112. In an embodiment, the counter-doped regions are at least an order of magnitude greater in doping concentration in order to sufficiently overwhelm (counter-dope) the first included dopant to dominate the doping characteristic. However, in that embodiment, the counter-doped regions are no more than approximately two orders of magnitude greater in doping concentrations such that conductivity differences of counter-doped versus non-counter-doped regions does not impact ultimate performance and efficiency of the solar cell.

In another aspect, as described briefly above, a shadow mask is used to direct the phosphorous implanting described in association with FIG. 1C. In one such embodiment, a stationary graphite shadow mask is used for implantation. As an example, FIG. 3A schematically illustrates a cross-sectional view of an inline platform for patterned implant involving a traveling wafer and a stationary shadow mask, in accordance with an embodiment of the present disclosure. FIG. 3B illustrates an implant sequence through graphite proximity masks in the apparatus of FIG. 3A, in accordance with an embodiment of the present disclosure. Referring to FIG. 3A, an inline platform 300 includes a wafer input region 302, an implant source 304 (e.g., ion implantation or plasma immersion), and an output region 306. A stationary stencil mask 308, such as a stationary graphite mask, is held in proximity to, but not in contact with, a substrate 310 to provide an implanted substrate 312. In another embodiment, a silicon shadow mask, which may contact the substrate 312, may be used for implantation.

Overall, although certain materials are described specifically above, some materials may be readily substituted with others with other such embodiments remaining within the spirit and scope of embodiments of the present disclosure. For example, in an embodiment, a different material substrate, such as a group III-V material substrate, can be used instead of a silicon substrate. Furthermore, it is to be understood that, where N+ and P+ type doping is described specifically, other embodiments contemplated include the opposite conductivity type, e.g., P+ and N+ type doping, respectively. Additionally, although reference is made significantly to back contact solar cell arrangements, it is to be appreciated that approaches described herein may have application to front contact solar cells as well. In other embodiments, the so-called trench-free process described above may be implemented to ultimately fabricate trench-contact solar cells. For example, a process flow such as described above may first be implemented, and trenches may subsequently be formed between the emitter regions.

Thus, methods of fabricating solar cells having trench-free emitter regions, and the resulting solar cells, have been disclosed. As a general representative approach, FIG. 4 is a flowchart 400 listing operations in another method of fabricating a solar cell, in accordance with an embodiment of the present disclosure. Referring to flowchart 400 of FIG. 4, a method of fabricating alternating N-type and P-type emitter regions of a solar cell involves, at operation 402, forming a thin dielectric layer on a portion of a back surface of a substrate. The method also involves, at operation 404, forming a first polycrystalline silicon emitter region on a first portion of the thin dielectric layer. The method also involves, at operation 406, forming a second polycrystalline silicon emitter region on a second portion of the thin dielectric layer proximate to the first polycrystalline silicon emitter region. In one embodiment, a total concentration of an impurity of a first conductivity type in the first polycrystalline silicon emitter region is at least an order of magnitude greater than a total concentration of an impurity of a second, opposite, conductivity type in the second polycrystalline silicon emitter region.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A solar cell, comprising:
a substrate having a light-receiving surface and a back surface;
a thin dielectric layer disposed on a portion of the back surface of the substrate;
a first polycrystalline silicon emitter region disposed on a first portion of the thin dielectric layer and doped with an impurity of a first conductivity type; and
a second polycrystalline silicon emitter region disposed on a second portion of the thin dielectric layer proximate to the first polycrystalline silicon emitter region disposed on the first portion of the thin dielectric layer, the second polycrystalline silicon emitter region doped with an impurity of a second, opposite, conductivity type, wherein a total concentration of the impurity of the first conductivity type in the first polycrystalline silicon emitter region is at least an order of magnitude greater than a total concentration of the impurity of the second conductivity type in the second polycrystalline silicon emitter region.

2. The solar cell of claim 1, further comprising:
a P/N junction between the first polycrystalline silicon emitter region and the second polycrystalline silicon emitter region.

3. The solar cell of claim 1, wherein the impurity of the first conductivity type in the first polycrystalline silicon emitter region is an N-type impurity, and the impurity of the second conductivity type in the second polycrystalline silicon emitter region is a P-type impurity.

4. The solar cell of claim 3, wherein the N-type impurity is phosphorous and the total concentration of the impurity of the first conductivity type in the first polycrystalline silicon emitter region is approximately 1E20 atoms/cm³, and wherein the P-type impurity is boron and the total concentration of the impurity of the second conductivity type in the second polycrystalline silicon emitter region is approximately 1E18 atoms/cm³.

5. The solar cell of claim 1, wherein the first polycrystalline silicon emitter region further comprises the impurity of the second conductivity type.

6. The solar cell of claim 5, wherein the total concentration of the impurity of the first conductivity type in the first polycrystalline silicon emitter region is approximately two orders of magnitude greater than the total concentration of the impurity of the second conductivity type in the second polycrystalline silicon emitter region and in the first polycrystalline silicon emitter region.

7. The solar cell of claim 1, further comprising:
a first conductive contact structure electrically connected to the first polycrystalline silicon emitter region; and
a second conductive contact structure electrically connected to the second polycrystalline silicon emitter region.

8. A method of fabricating a solar cell, the method comprising:
forming a thin dielectric layer on a portion of a back surface of a substrate, the substrate having a light-receiving surface opposite the back surface;
forming a first polycrystalline silicon emitter region on a first portion of the thin dielectric layer and doped with an impurity of a first conductivity type; and
forming a second polycrystalline silicon emitter region on a second portion of the thin dielectric layer proximate to the first polycrystalline silicon emitter region, the second polycrystalline silicon emitter region doped with an impurity of a second, opposite, conductivity type, wherein a total concentration of the impurity of the first conductivity type in the first polycrystalline silicon emitter region is at least an order of magnitude greater than a total concentration of the impurity of the second conductivity type in the second polycrystalline silicon emitter region.

9. A solar cell fabricated according to the method of claim 8.

10. A method of fabricating alternating N-type and P-type emitter regions of a solar cell, the method comprising:
forming a boron-containing silicon layer above a portion of a substrate by an in situ deposition process;
implanting first regions, but not second regions, of the boron-containing silicon layer with phosphorous ions to provide phosphorous-implanted regions of the boron-containing silicon layer;
heating to provide N-type polycrystalline silicon emitters in the first regions and to provide P-type polycrystalline silicon emitters in the second regions; and
forming a plurality of conductive contact structures, each of the N-type polycrystalline silicon emitters and the P-type polycrystalline silicon emitters electrically connected to one of the plurality of conductive contact structures.

11. The method of claim 10, wherein forming the boron-containing silicon layer comprises forming a boron-containing amorphous silicon layer, and wherein the heating comprises crystallizing the boron-containing amorphous silicon layer.

12. The method of claim 10, wherein forming the boron-containing silicon layer comprises forming a boron-doped polycrystalline silicon layer, and wherein the heating comprises activating the phosphorous ions of the phosphorous-implanted regions to form phosphorous-doped regions.

13. The method of claim 12, wherein forming the boron-doped polycrystalline silicon layer comprises using a plasma-enhanced chemical vapor deposition (PECVD) process.

14. The method of claim 10, wherein implanting the boron-containing silicon layer with phosphorous ions comprises implanting through a shadow mask.

15. The method of claim 14, wherein implanting through the shadow mask comprises implanting through a graphite shadow mask positioned off of, but in close proximity to, the boron-containing silicon layer.

16. The method of claim 14, wherein implanting through the shadow mask comprises implanting through a silicon shadow mask positioned on the boron-containing silicon layer.

17. The method of claim 10, wherein the heating comprises forming a P/N junction between adjacent ones of the N-type polycrystalline silicon emitters and P-type polycrystalline silicon emitters.

18. The method of claim 10, wherein the heating provides the N-type polycrystalline silicon emitters comprising a total phosphorous dopant concentration of at least an order of magnitude greater than a total boron dopant concentration of the P-type polycrystalline silicon emitters.

19. The method of claim 10, wherein forming the boron-containing silicon layer comprises forming on a portion of a thin oxide layer formed on the substrate.

20. A solar cell fabricated according to the method of claim 10.
